(19) United States
(12) Patent Application Publication
(10) Pub. No.: US 2010/0068383 A1
(43) Pub. Date: Mar. 18, 2010

(54) FILM DEPOSITION APPARATUS, FILM DEPOSITION METHOD, AND COMPUTER READABLE STORAGE MEDIUM

(75) Inventors: Hitoshi Kato, Oshu-Shi (JP); Yasushi Takeuchi, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/559,575

(22) Filed: Sep. 15, 2009

(30) Foreign Application Priority Data
Sep. 17, 2008 (JP) 2008-238438

(51) Int. Cl. C23C 16/455; C23C 16/00; C23C 16/46

(52) U.S. Cl. 427/255.28; 118/728; 118/725

(57) ABSTRACT

A deposition apparatus includes plural first plate members arranged within a hermetically-sealable cylindrical chamber, wherein the plural first plate members each having an opening are arranged in a first direction along a center axis of the chamber with a first clearance therebetween; and plural second plate members arranged in the first direction with the first clearance therebetween, the plural second plate members being reciprocally movable through the openings of the plural first plate members. A first pair of first plate members among the plural first plate members provides a first passage for a first gas flowing in a second direction toward an inner circumferential surface of the chamber. A second pair of first plate members among the plural first plate members provides a second passage for a second gas flowing in the second direction. A pair of second plate members among the plural second plate members supports a wafer.

### CROSS-REFERENCE TO RELATED APPLICATIONS

The present application is based on Japanese Patent Application No. 2008-238438 filed with the Japanese Patent Office on Sep. 17, 2008, the entire contents of which are hereby incorporated herein by reference.

### BACKGROUND OF THE INVENTION

1. Field of the Invention

The present invention relates to a film deposition apparatus and a film deposition method for depositing a film on a substrate by carrying out plural cycles of supplying in turn at least two source gases to the substrate in order to form plural layers of a reaction product, and a computer readable storage medium storing a computer program for carrying out the film deposition method.

2. Description of the Related Art

Along with further miniaturization of a circuit pattern in semiconductor devices, various films constituting the semiconductor devices are required to be thinner and more uniform. As a film deposition method that can address such requirements, a so-called Molecular Layer Deposition (MLD), which is also called Atomic Layer Deposition (ALD), has been known that can provide accurately controlled film thickness and excellent uniformity.

In this film deposition method, a first reaction gas is supplied to a reaction chamber where a substrate is housed to allow first reaction gas molecules to be adsorbed on the substrate; and after the first reaction gas is purged from the reaction chamber, a second reaction gas is supplied to the reaction chamber to allow second reaction gas molecules to be adsorbed on the substrate, thereby causing the gas molecules of the first and the second gases to react with each other and producing a monolayer of the reaction products on the substrate. Then, the second reaction gas is purged from the reaction chamber, and the above procedures are repeated predetermined times, thereby depositing a film having a predetermined thickness. Because the first and the second reaction gas molecules adsorbed one over the other on the substrate react with each other, which forms a monolayer of the reaction product on the substrate, film thickness and uniformity may be controlled at a monolayer level.

It has been known that such a film deposition method is carried out in a film deposition apparatus described in Patent Document 1 listed below.

The ALD apparatus disclosed in Patent Document 1 includes a deposition chamber that is divided into two or more deposition regions that are integrally connected one to another, and a wafer support that is movable between the two or more deposition regions within the deposition chamber. The two or more deposition regions are coupled by an aperture, which has a size through which the wafer support can pass while reducing intermixing of deposition gases between the deposition regions. In addition, Patent Document 1 describes that an inert gas may provide a laminar flow around an area of the aperture, in order to further reduce the intermixing around the aperture.

Patent Document 1: U.S. Pat. No. 7,085,616.

### SUMMARY OF THE INVENTION

Generally, a person having ordinary skill in the art has known that a gas flow is not easily controlled in a chamber. When the film deposition apparatus disclosed in Patent Document 1 is considered based on such knowledge, it is difficult to say that the aperture can sufficiently reduce the intermixing of the deposition gases. In addition, even when the inert gas is supplied around an area of the aperture, it is not apparent that the inert gas provides the laminar flow so that the intermixing of the deposition gases is sufficiently minimized. Moreover, Patent Document 1 only describes a single-wafer film deposition apparatus, and does not disclose any measures to improve throughput of MLD, which usually takes a longer time than a conventional film deposition.

The present invention has been made in view of the above, and provides a film deposition apparatus that is configured to reduce intermixing of source gases in order to realize an appropriate MLD mode film deposition, and improve an MLD throughput; a film deposition method using the film deposition apparatus; and a computer readable storage medium storing a computer program that causes the film deposition apparatus to carry out the film deposition method.

A first aspect of the present invention provides a film deposition apparatus including a plurality of first plate members arranged within a hermetically sealable cylindrical chamber, wherein the plurality of the first plate members are arranged in a first direction, along a center axis of the chamber with a first clearance therebetween, each of the first plate members having an opening; and a plurality of second plate members arranged in the first direction with the first clearance therebetween, wherein the plurality of the second plate members are reciprocally movable through the openings of the plurality of the first plate members, wherein a first pair of first plate members among the plurality of the first plate members is configured to provide a first gas flow passage where a first gas flows in a second direction toward an inner circumferential surface of the chamber, wherein a second pair of first plate members among the plurality of the first plate members is configured to provide a second gas flow passage where a second gas flows in the second direction, and wherein a pair of second plate members among the plurality of the second plate members is configured to provide a wafer housing portion.

A second aspect of the present invention provides a film deposition method performed in a film deposition apparatus including a plurality of first plate members arranged within a hermetically sealable cylindrical chamber, wherein the plurality of the first plate members are arranged in a first direction along a center axis of the chamber with a first clearance therebetween, each of the first plate members having an opening, and a plurality of second plate members arranged in the first direction with the first clearance therebetween, wherein the plurality of the second plate members are reciprocally movable through the openings of the plurality of the first plate members. The film deposition method includes steps of loading a wafer into a space between a pair of second plate members among the plurality of the second plate members; flowing a first gas to a space between a first pair of first plate members among the plurality of the first plate members in a second direction toward an inner circumferential surface of the chamber; flowing a second gas to a space between a second pair of first plate members among the plurality of the first plate members in the second direction; and reciprocally moving the plurality of the second plate members in order to alternately expose the wafer to the first gas and the second gas.

A third aspect of the present invention provides a computer readable storage medium storing a program to perform the film deposition method.

### BRIEF DESCRIPTION OF THE DRAWINGS

FIG. 1 is a schematic view illustrating a film deposition apparatus according to an embodiment of the present invention;

FIG. 2 is an enlarged schematic view of a reaction chamber of the film deposition apparatus of FIG. 1;

FIG. 3 is another enlarged schematic view of the reaction chamber of the film deposition apparatus of FIG. 1;

FIG. 4 is a schematic view illustrating a spatial relationship among an inner boat, an outer boat, a gas supplying pipe, and an evacuation port of the reaction chamber of the film deposition apparatus of FIG. 1;

FIG. 5 is a time chart illustrating an example of a film deposition method according to an embodiment of the present invention;

FIGS. 6A through 6H are explanatory views for explaining a molecular layer deposition carried out in the film deposition apparatus of FIG. 1;

FIG. 7 is a schematic view illustrating a modification example of the film deposition apparatus of FIG. 1; and

FIG. 8 is another schematic view illustrating the modification example of the film deposition apparatus of FIG. 1.

### DETAILED DESCRIPTION OF THE PREFERRED EMBODIMENT

According to an embodiment of the present invention, there is provided a film deposition apparatus that is configured to reduce intermixing of source gases in order to realize an appropriate MLD mode film deposition, and improve an MLD throughput, a film deposition method using the film deposition apparatus, and a computer readable storage medium storing a computer program that causes the film deposition apparatus to carry out the film deposition method.

Non-limiting, exemplary embodiments of the present invention will now be described with reference to the accompanying drawings. In the drawings, the same or corresponding reference marks are given to the same or corresponding members or components. It is noted that the drawings are illustrative of the invention, and there is no intention to indicate scale or relative proportions among the members or components. Therefore, the specific size should be determined by a person having ordinary skill in the art in view of the following non-limiting embodiments.

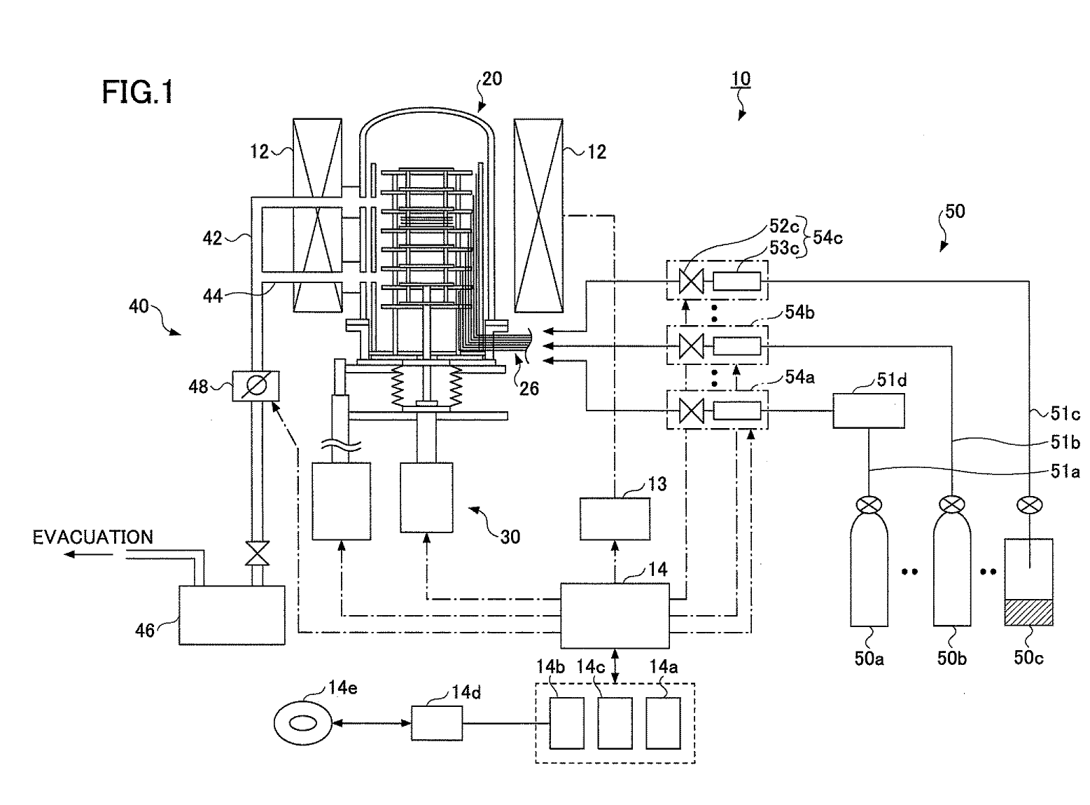

FIG. 1 is a schematic view illustrating a film deposition apparatus according to an embodiment of the present invention. As shown, a film deposition apparatus 10 according to this embodiment includes a vertical reaction chamber 20, a driving mechanism 30 that drives a wafer boat (described later) in the reaction chamber 20, an evacuation system 40 that evacuates the reaction chamber 20, a gas supplying system 50 as a gas source that introduces gases to the reaction chamber 20, a heater 12 that heats a wafer in the reaction chamber 20, and a controller 14 that controls constituting components, members and the like of the film deposition apparatus 10 thereby controlling film deposition.

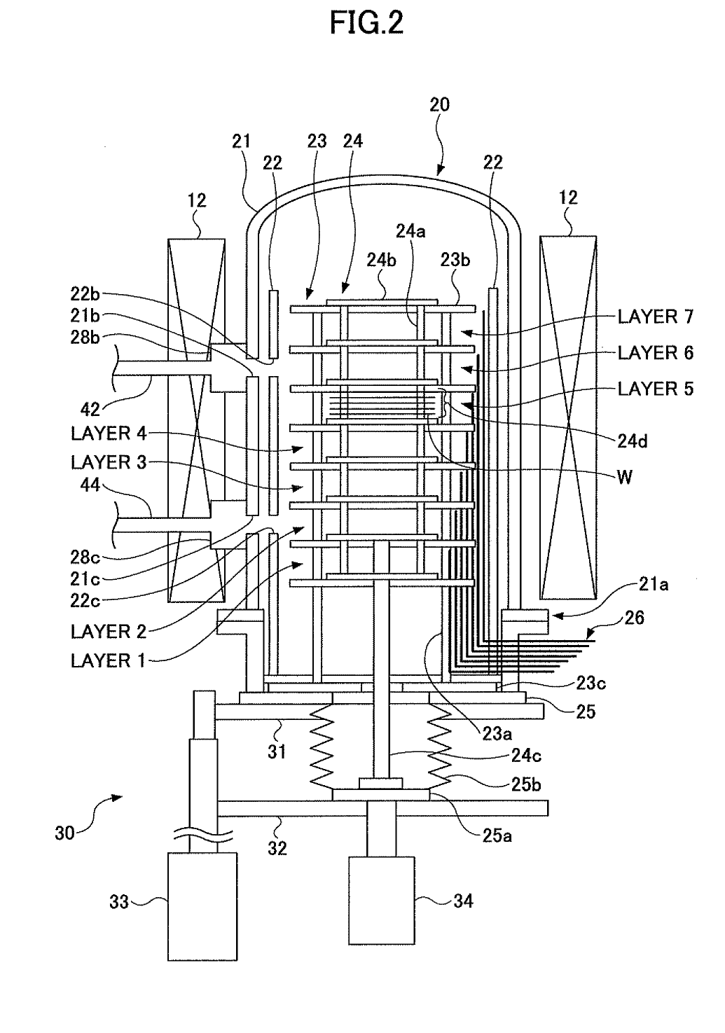

First, the reaction chamber 20 is explained with reference to FIGS. 2 through 4. As shown in FIG. 2, the reaction chamber 20 includes a vertical cylindrical outer tube 21 with a closed top, which is attached at the bottom on a flange 21a, an inner tube 22 arranged inside the outer tube 21, an outer boat 23 arranged inside the inner tube 22, an inner boat 24 that is arranged inside the outer boat 23 and supports a wafer W, and plural gas supplying pipes 26 extending along an inner circumferential wall of the inner tube 22 in order to eject corresponding gases in a horizontal direction.

The outer boat 23 includes plural pillars 23a, and eight annular plates 23b arranged with an equal clearance between every two vertically adjacent annular plates 23b and supported by the pillars 23a. The annular plates 23b serve as flow defining plates that define gas flow passage where a gas flows in a direction toward an inner circumferential direction of the inner tube 22 (horizontal direction in the illustrated example) within the inner tube 22 as described later. Therefore, a width (half a difference between an outer diameter and an inner diameter) of the annular plate 23b is preferably determined so that the annular plate 23b can serve as the flow defining plate, taking into consideration a size of the wafer W and inner diameters of the outer tube 21, the inner tube 22, the outer boat 23, and the inner boat 24. Every two vertically adjacent annular plates 23b create one layer, and thus a total of seven layers are created in the outer boat 23. For convenience of explanation, these layers are referred to as a layer 1, a layer 2, . . . , a layer 7 from bottom to top, as shown in FIG. 2.

In addition, the outer boat 23 is attached at the bottom of the pillars 23a on a pedestal 23c, and the pedestal 23c is attached on a flange 25. The flange 25 is supported by a first elevator 31. The first elevator 31 is driven in a vertical direction by a driving unit 33 of the driving mechanism 30. With this, the flange 25 is upwardly pressed onto the flange 21a via a sealing member (not shown), thereby hermetically sealing the inside space of the outer tube 21.

The inner boat 24 includes plural pillars 24a, and eight circular plates 24b arranged with an equal clearance between every two vertically adjacent circular plates 24b and supported by the pillars 24a. A space between a third circular plate 24b and a fourth circular plate 24b from the top among the eight circular plates 24b serves as a wafer housing portion 24d. Specifically, plural slits are made in the pillars 24a at substantially equal vertical intervals in the wafer housing portion 24d, and the wafers are supported by the slits in the pillars 24a. The vertical intervals of the slits may be determined by the number of the wafers W housed in the wafer housing portion 24d, a source gas to be used, and the like. In addition, only one wafer W may be housed in the wafer housing portion 24d.

A lowermost circular plate 24b of the inner boat 24 has a through hole in the center, and a second circular plate 24b from the bottom has a concave portion (not shown) in the center on the lower surface. The inner boat 24 is supported by a supporting rod 24c that passes through the through hole of the lowermost circular plate 24b and is engaged with the concave portion of the second circular plate 24b from the bottom. The supporting rod 24c downwardly extends through a through hole made in the center of the flange 25, and attaches to a second elevator 32 via a circular member 25a. With this, the inner boat 24 is centered relative to the inner tube 22 and the outer tube 21, in this embodiment. A bellow seal 25b is provided between the flange 25 and the circular member 25a, which keeps the outer tube 21 hermetically sealed and at the same time allows the supporting rod 24c and thus the inner boat 24 to move in a vertical direction. In addition, the circular member 25a serves as a rotary feedthrough. Namely, the circular member 25a allows the supporting rod 24c to rotatably extend through the through hole made in the center of the circular member 25a while keeping airtightness by a magnetic fluid sealing. The supporting rod 24c is connected at the bottom to a motor 34, according to which the inner boat 24 can be rotated around a center axis of the supporting rod 24c.

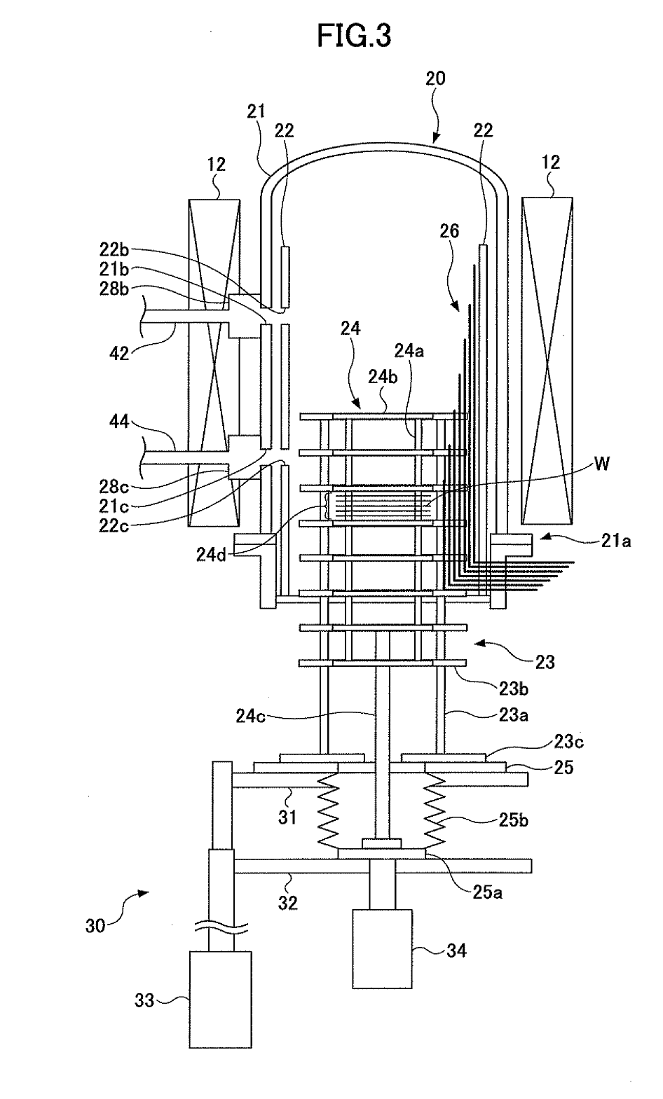

The second elevator 32 can be vertically moved separately from or along with the first elevator 31 by the driving unit 33. Namely, when the first elevator 31 and the second elevator 32 are vertically moved in unison, the inner boat 24 and the outer boat 23 are vertically moved accordingly, as shown in FIG. 3. In such a manner, the inner boat 24 and the outer boat 23 are loaded/unloaded to/from the inner tube 22. In addition, when the second elevator 32 is vertically moved relative to the first elevator 31, the inner boat 24 is vertically moved relative to the outer boat 23 accordingly.

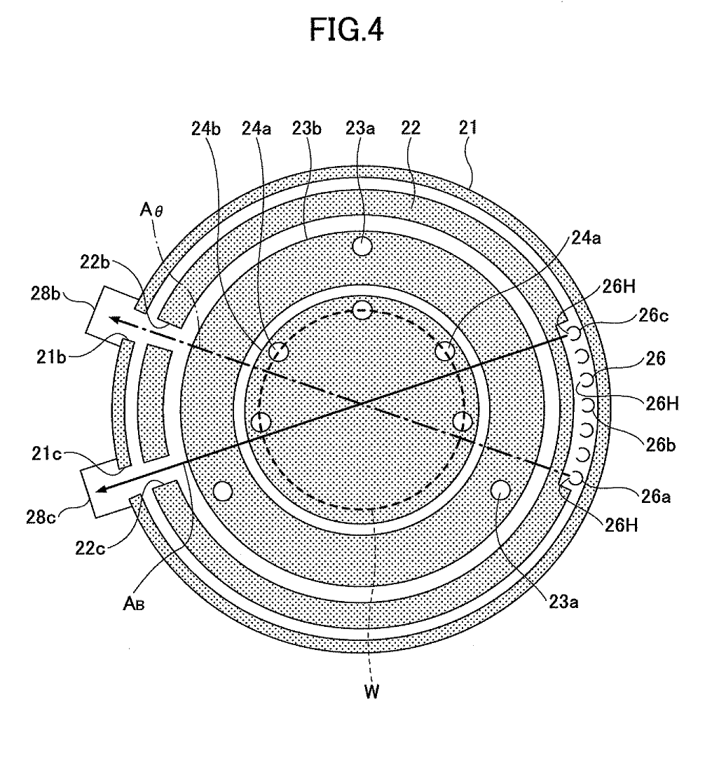

Next, a positional relationship between the inner boat 24 and the outer boat 23 is explained with reference to FIG. 4. As shown, the inner boat 24 and the outer boat 23 are arranged in such a manner that the circular plate 24b of the inner boat 24 and the annular plate 23b of the outer boat 23 are positioned concentrically with each other. In addition, a space between the circular plate 24b and the annular plate 23b (a difference between the outer diameter of the circular plate 24b and the inner diameter of the annular plate 23b) is preferably as small as possible as described below. In this embodiment, because the inner boat 24 and the outer boat 23 are arranged on the flange 25 (see FIG. 2 or 3), the inner boat 24 (circular plate. 24b) and the outer boat 23 (annular plate 23b) can be positioned relative to each other with high precision.

Incidentally, although the outer boat 23 is configured in such a manner that the annular plates 23b are supported by the pillar 23a in this embodiment, the annular plates 23b may be attached on the inner circumferential wall of the inner tube 22 with a predetermined clearance therebetween. In addition, the annular plates 23b may also be attached on the inner circumferential wall of the outer tube 21 without using the inner tube 22. However, from a viewpoint of positioning precision between the circular plate 24b and the annular plate 23b, the outer boat 23 including the annular plates 23b is preferably arranged via the pedestal 23c on the flange 25 by which the inner boat 24 is positioned.

In addition, as best illustrated in FIG. 3, a clearance between two vertically adjacent circular plates 24b of the inner boat 24 is substantially the same as the clearance between two vertically adjacent annular plates 23b of the inner boat 23. Therefore, when the circular plate 24b is positioned at the same elevation of one of the annular plates 23b, the inner opening of the annular plate 23b is substantially closed by the circular plate 24b. Namely, the layers 1 through 7 are defined by not only the annular plates 23b serving as the flow defining plates but also the circular plates 24b. With this, intermixing of the gases between the layers can be sufficiently reduced. The difference between the inner diameter of the annular plate 23b and the outer diameter of the circular plate 24b falls preferably within a range from about 0.1 mm to about 10 mm. If the difference is smaller than 0.1 mm, the circular plate 24b may hit the annular plate 23b, so that the inner boat 24 may not be moved vertically relative to the outer boat 23, or the inner boat 24 and/or the outer boat 23 may be damaged or broken. Moreover, if the circular plate 24b contacts the annular plate 23b, particles may be generated, so that the wafer W is contaminated. On the other hand, if the difference is greater than 10 mm, the gases can flow through the space between the circular plate 24b and the annular plate 23b, and the gases are mixed between the layers, so that MLD mode film deposition cannot be appropriately carried out. Namely, the difference between the inner diameter of the annular plate 23b and the outer diameter of the circular plate 24b is preferably as small as possible as long as the circular plate 24b does not contact the annular plate 23b, and may be determined taking into consideration a machining accuracy of the circular plate 24b and the annular plate 23b, a positioning accuracy of the inner boat 24 and the outer boat 23, and in addition deposition conditions such as gas flow rates, pressure and the like. Specifically, the difference is more preferably in a range from about 0.1 mm to about 5 mm.

Referring again to FIG. 2, the reaction chamber 20 is provided with seven gas supplying pipes 26 that hermetically penetrate the outer tube 21 and the inner tube 22, are bent upwardly inside the inner tube 22, and vertically extend along the inner wall of the inner tube 22. These seven gas supplying pipes 26 have lengths corresponding to elevations of the layers 1 through 7. In addition, the gas supplying pipes 26 have closed tops and ejection holes 26H (FIG. 4) on the side walls near the tops. With this, the gas supplying pipes 26 can eject corresponding gases toward the corresponding layers 1 through 7, thereby creating horizontal gas flows in the layers 1 through 7.

The gas supplying system 50 connected to the gas supplying pipes 26 includes gas supplying sources 50a, 50b, 50c, gas lines 51a, 51b, 51c that connect the gas supplying sources 50a, 50b, 50c with the corresponding gas supplying pipes 26, gas controllers 54a, 54b, 54c provided in the corresponding gas lines 51a, 51b, 51c, as shown in FIG. 1. The gas controller 54c includes an open/close valve 52c and a mass flow meter (MFC) 53c. Although reference numerals are omitted for the gas controllers 54a and 54b in FIG. 1, these gas controllers have the same configuration as the gas controller 54c. The gas supplying source 50a may be, for example, but not limited to a gas cylinder filled with oxygen (O₂) gas, and the gas line 51a may be provided with an ozone generator 51d in order to generate ozone (O₃) gas from the O₂ gas.

The gas line 51a is connected to the gas supplying pipe 26a (FIG. 4) corresponding to the layer 2, and thus the O₃ gas is supplied to the layer 2. The gas line 51b is connected to the gas supplying pipe 26b corresponding to the layer 4. The gas supplying source 50b may be a gas cylinder filled with nitrogen gas (N₂) gas, so that the N₂ gas is supplied to the layer 4. In addition, the gas line 51c is connected to the gas supplying pipe 26c corresponding to the layer 6, and the gas supplying source 50c may be a bis (tertiary-butylamino) silane (BTBAS) supplier filled with BTBAS. Therefore, the BTBAS gas is supplied to the layer 6.

Incidentally, although gas lines connected to the gas supplying pipes 26 corresponding to the layers 1, 3, 5, 7 are not shown in the drawings, these gas supplying pipes 26 are provided with the same configuration as the gas supplying pipe 26b corresponding to the layer 4. Therefore, the N₂ gas is supplied to the layers 1, 3, 5, 7.

Referring to FIG. 2 (or FIG. 3), an opening 22b is formed in the inner tube 22, and an opening 21b is formed in the outer tube 21. The openings 22b, 21b are located at an elevation corresponding to the layer 6 where the BTBAS gas may flow and located symmetrically to the gas supplying pipe 26 corresponding to the layer 6. In addition, an evacuation port 28b is hermetically attached at one end to the opening 21b outside the outer tube 21, and connected at the other end to an evacuation pipe 42 connected to the evacuation system 40. On the other hand, an opening 22c and an opening 21c are formed in the inner tube 22 and the outer tube 21, respectively, at an elevation corresponding to the layer 2 where the O₃ gas may flow, and the openings 22c and 21c are arranged symmetrically to the gas supplying pipe 26 corresponding to the layer 2. In addition, an evacuation port 28c is hermetically attached at one end to the opening 21c outside the outer tube 21, and connected at the other end to an evacuation pipe 44, which converges to the evacuation pipe 42, as shown in FIG. 1.

Next, a positional relationship among the evacuation port 28b (28c), the opening 22b (22c), and the opening 21b (21c) is explained with reference to FIG. 4. In order to better illustrate the relationship, plan views taken along planes spreading in the layer 2 and 6, respectively, are superposed. As shown in FIG. 4, the evacuation port 28b, the opening 22b and the opening 21b oppose the gas supplying pipe 26a for ejecting the O₃ gas across the inner boat 24 (circular plate 24b). In addition, the evacuation port 28c, the opening 22c and the opening 21c oppose the gas supplying pipe 26c for ejecting the BTBAS gas across the inner boat 24 (circular plate 24b). With these configurations, the O₃ gas flows substantially as shown by an arrow A_{O}, and the BTBAS gas flows substantially as shown by an arrow A_{B} in FIG. 4. Because of such flows, intermixing of the reaction gases through a space between the inner tube 22 and the outer tube 21 can be further reduced.

Referring again to FIG. 1, the evacuation pipe 44 is provided with a pressure control valve 48 that controls a pressure in the outer tube 21. In addition, the evacuation pipe 44 is connected to a vacuum pump 46 such as a dry pump. A pressure gauge (not shown) is hermetically inserted into the outer tube 21. With this, the pressure in the outer tube 21 is measured by the pressure gauge, and thus controlled by the pressure control valve 48 in accordance with the measured pressure.

In addition, the heater 12 arranged to surround the outer tube 21 is connected to a power source 13, as shown in FIG. 1. A temperature of the wafer W is indirectly measured by, for example, a thermocouple inserted into a space between the inner tube 22 and the outer boat 23, and electric power supplied to the heater 12 from the power source 13 is controlled in accordance with the measured temperature, thereby controlling the temperature of the wafer W. Incidentally, the heater 12 may be composed of a tantalum wire and the like. In addition, the heater 12 may be multi-stage heater, and each stage may be separately controlled, so that the temperature uniformity across the wafer W can be improved.

In addition, gas supplying by the gas controller 54a, 54b, 54c, vertical movement of the elevators 31, 32, rotation of the inner boat 24 by the motor 34, pressure in the outer tube 21 by the pressure control valve, 48, temperature of the wafer W heated by the heater 12, and the like are managed by a control portion 14. The control portion 14 may include a computer in order to cause the film deposition apparatus 10 to carry out MLD deposition in accordance with a computer program. This program includes groups of instructions to cause the film deposition apparatus 10 to execute steps of, for example, a film deposition method described later. In addition, the control portion 14 is connected to a display unit 14a that displays recipes, process status and the like, a memory device 14b that stores the program and process parameters, and an interface device 14c that may be used along with the display unit 14a to edit the program and modify the process parameters. Moreover, the memory device 14b is connected to an input/output (I/O) device 14d through which the program, the recipes, and the like are loaded/unloaded from/to a computer readable storage medium 14e storing the program and the like. With this, the program and the recipe are loaded to the memory device 14b from the computer readable storage medium 14e in accordance with instruction input from the interface device 14c. The film deposition method described later is carried out in accordance with the program and the recipe loaded from the computer readable storage medium 14e. Incidentally, the computer readable storage medium 14e may be a hard disk (including a portable hard disk), a compact disk (CD), a CD-R/RW, a digital versatile disk (DVD)-R/RW, a flexible disk, a universal serial bus (USB) memory, a semiconductor memory, and the like. In addition, the program and the recipe may be downloaded through a communication line to the memory device 14b.

Next, a film deposition method according to an embodiment of the present invention, which may be carried out in the film deposition apparatus 10, is explained with reference to FIGS. 1, 2, and 5 through 8.

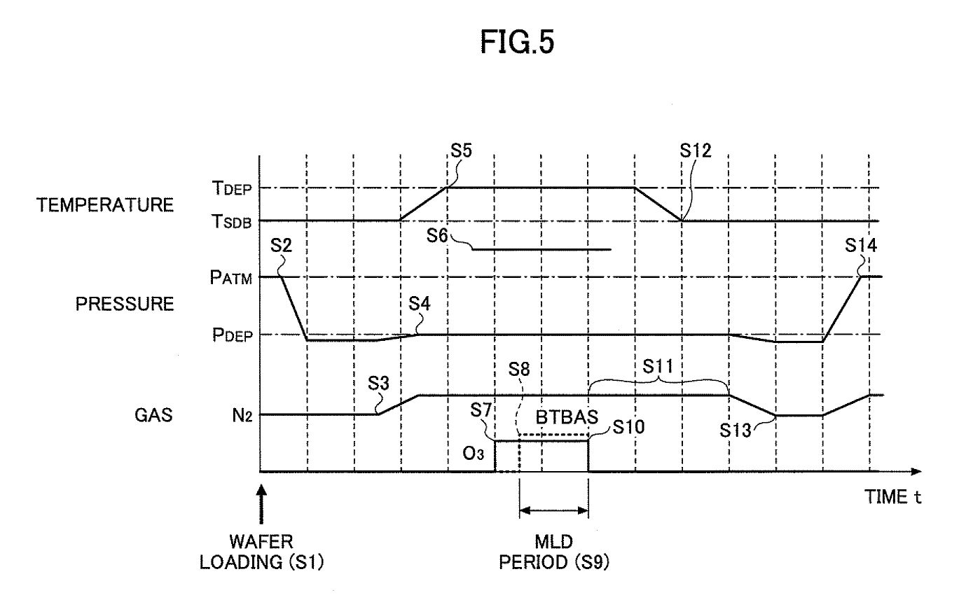

FIG. 5 is a time chart schematically illustrating a film deposition method according to this embodiment of the present invention. First, the first elevator 31 and the second elevator 32 (FIG. 2) are lowered, so that the outer boat 23 and the inner boat 24 are unloaded from the outer tube 21 and the inner tube 22. Next, plural wafers W are housed into the wafer housing portion 24d of the inner boat 24 by a wafer transfer unit (not shown). Then, the first elevator 31 and the second elevator 32 (FIG. 2) are raised, so that the outer boat 23 and the inner boat 24 are loaded into the outer tube 21 and the inner tube 22. With this, the wafer loading is completed (Step S1).

Next, the outer tube 21 is evacuated to vacuum by the vacuum pump 26 of the evacuation system 40 (Step S2). At this time, no gases are supplied to the outer tube 21, so that the outer tube 21 is evacuated to a lowest reachable pressure, which enables the outer tube 21 to be checked for leakage. After no leak is confirmed, the N₂ gas is supplied through the gas supplying pipes 26 from the gas supplying system 50 (Step S3). Specifically, the N₂ gas is supplied to the layers 1, 3-5, and 7. At the same time, the pressure control valve 48 is activated, so that the pressure in the outer tube 21 is set at a deposition pressure P_{DEP} (e.g., about 8 Torr (1.07 kPa)) (Step S4).

Then, the heater 12 is also activated, so that the wafer temperature is set at a deposition temperature T_{DEP} (e.g., about 350° C.) (Step S5). After the wafer temperature is stabilized at T_{DEP}, the inner boat 24 is rotated by the motor 34 (Step S6). The rotation speed may be within a range from 1 through 160 revolutions per minute (rpm), or from 1 through 30 rpm. In addition, the inner boat 24 may not be rotated.

Next, the O₃ gas is supplied to the layer 2 through the gas supplying pipe 26a from the gas line 51a of the gas supplying system 50 (Step S7), and the BTBAS gas is supplied to the layer 6 through the gas supplying pipe 26c from the gas line 51c of the gas supplying system 50 (see FIGS. 1 and 4) (Step S8). A flow rate of the O₃ gas may be within a range from about 1 standard liter per minute (slm) through about 10 slm, and a flow rate of the BTBAS gas may be within a range from about 1 standard cubic centimeter per minute (sccm) through about 300 sccm. The flow rates are not limited to the above ranges but may be adjusted in accordance with sizes of the outer tube 21 and the inner tube 22, a size of the wafer W, kinds of the reaction gases to be used, and the like.

In addition, flow rates of the N₂ gases flowing in the layers 1 and 3 are preferably equal to the flow rate of the O₃ gas flowing in the layer 2, and flow rates of the N₂ gases flowing in the layers 5 and 7 are preferably equal to the flow rate of the BTBAS gas flowing in the layer 6, from the following reasons. Because the clearances between the annular plates 23 b of the outer boat 23 are the same as the clearances between the circular plates 24b of the inner boat 24 and thus flow cross sections in the layers 1 through 7 are equal, no turbulent flow can be caused in the layers 1 through 3 (5 through 7), when the N₂ gases flow through the layers 1 and 3 (5 and 7) at the same flow rate as the O₃ (BTBAS) gas flowing in the layer 2 (6), thereby preventing the reaction gases to be mixed. Incidentally, the flow rate of gas flowing in the layer 6 may be adjusted to the same as the O₃ gas flowing in the layer 2 by adding a dilution gas such as N₂ gas, H₂ gas or inert gas to the BTBAS gas, or by supplying the BTBAS gas using a carrier gas. In this case, the flow rates of the gases flowing in the corresponding layers 1 through 7 are equal.

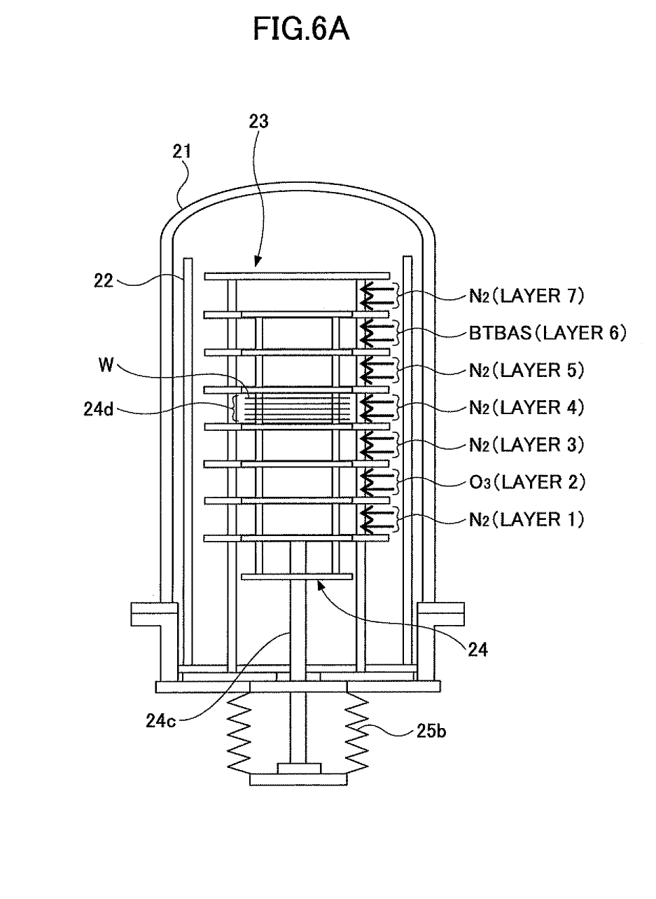

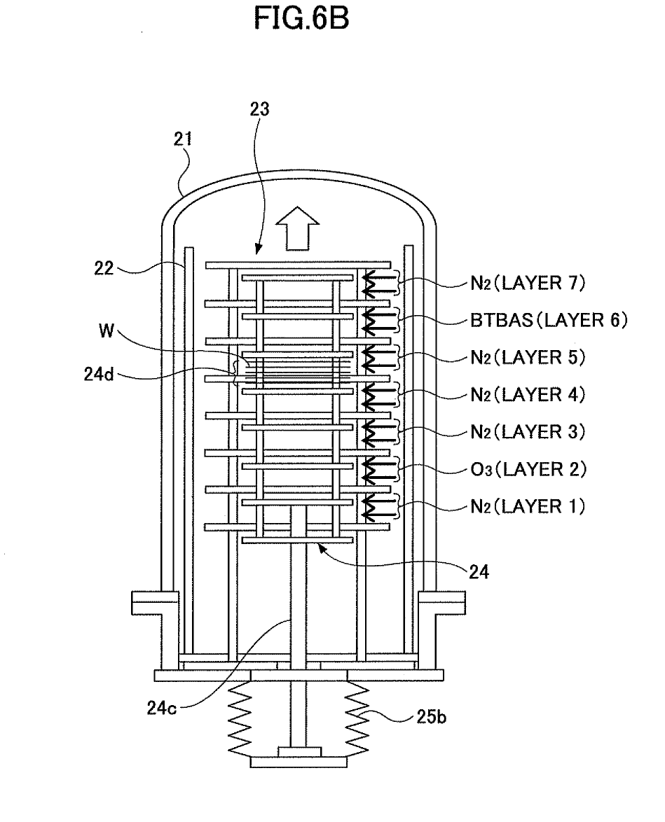

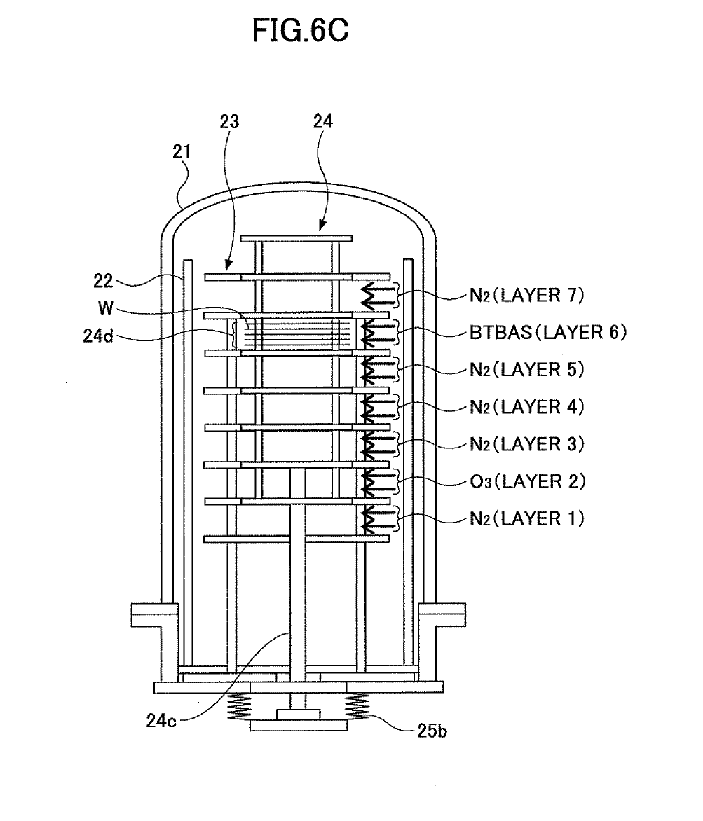

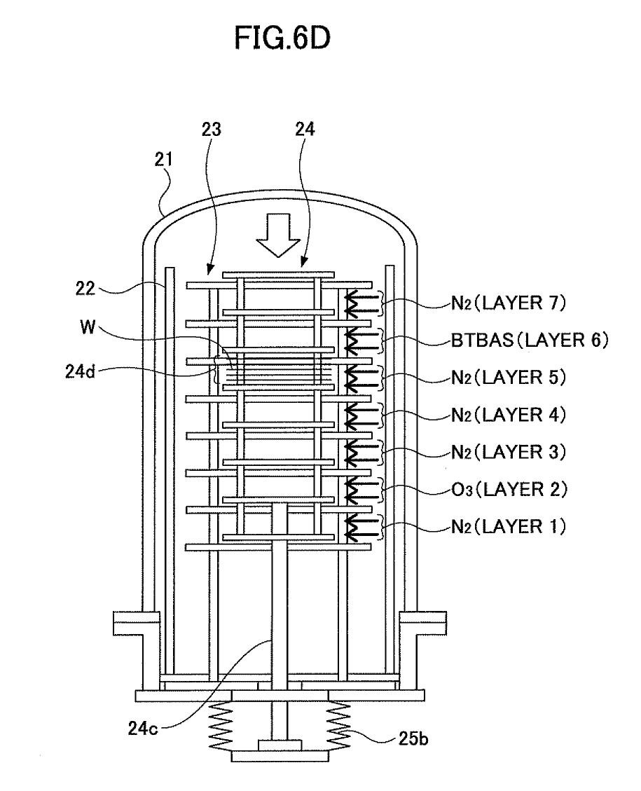

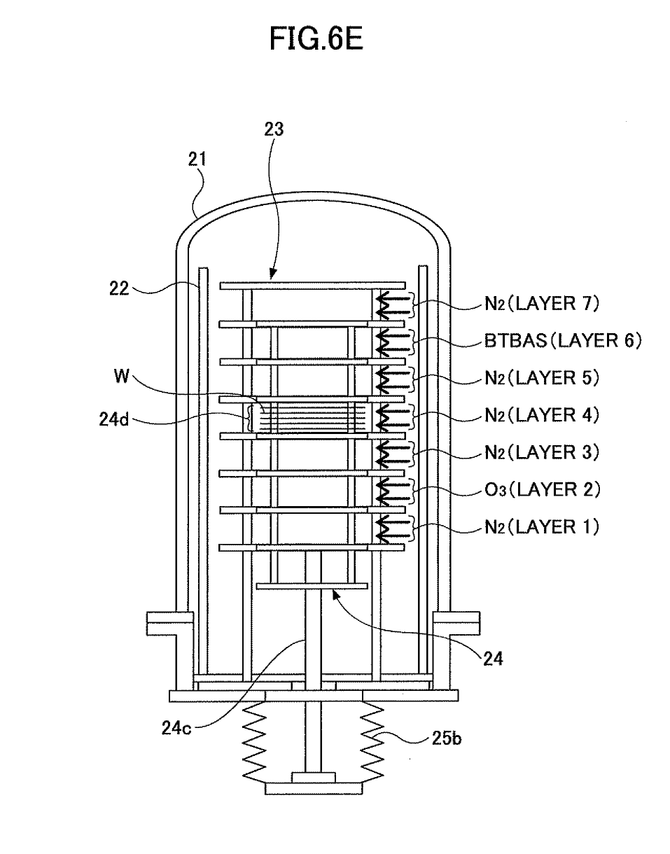

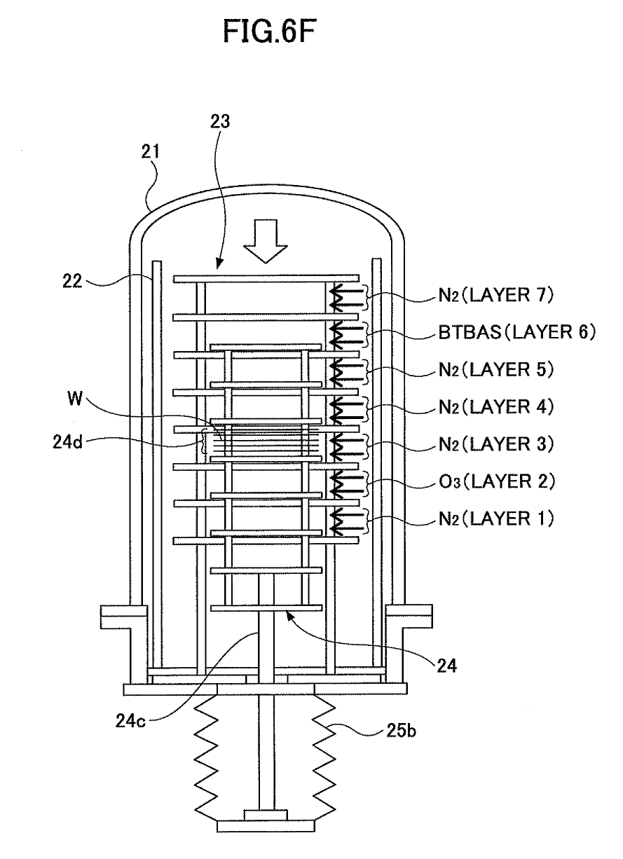

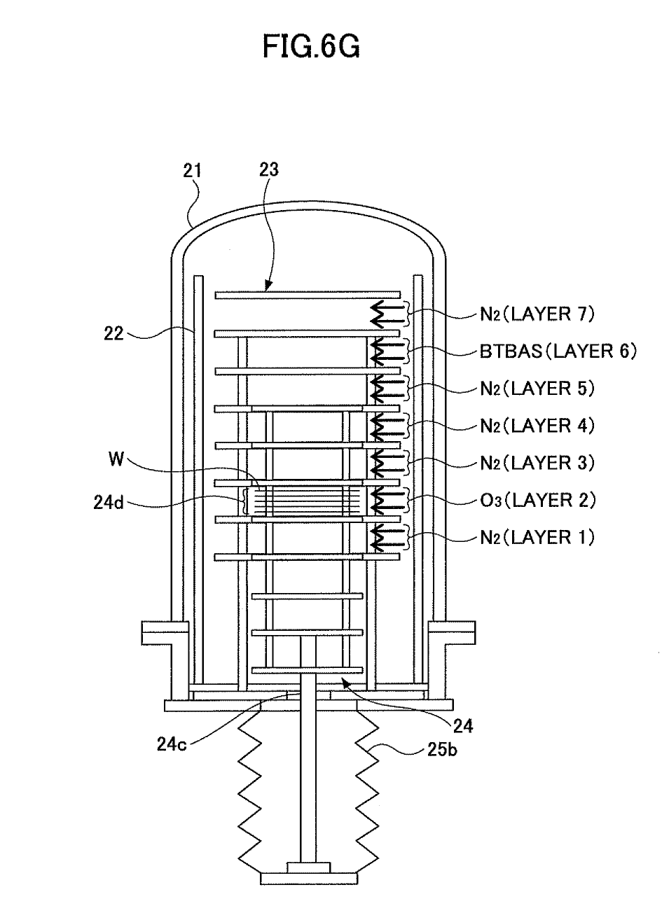

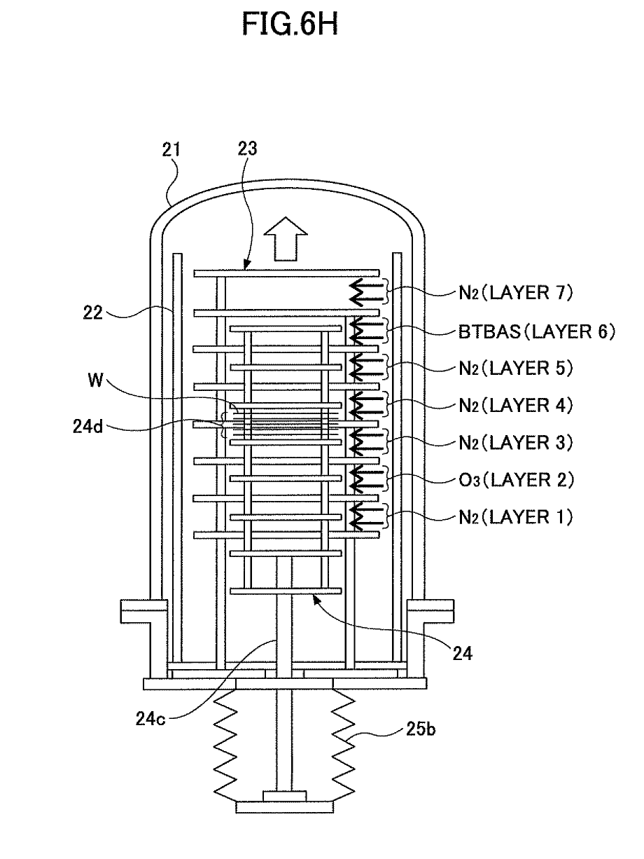

Subsequently, the inner boat 24 is moved upward and downward by the second elevator 32, so that the MLD is carried out (Step S9). Referring to FIGS. 6A through 6H, this deposition is explained. In FIGS. 6A through 6H, the gas supplying pipes, the evacuation ports, and the elevators are omitted as a matter of convenience.

First, the wafer housing portion 24d that houses the wafers W is located in the layer 4 in advance, as shown in FIG. 6A. In the layer 4, the N₂ gas is flowing from the gas supplying pipe 26b (FIG. 4), and thus the wafers W are exposed to the N₂ gas. Next, the inner boat 24 is moved upward from the layer 4 by the second elevator 32, as shown in FIG. 6B, and passes through the layer 5 to reach the layer 6, as shown in FIG. 6C. While the wafers W are continuously exposed to the N₂ gas until the wafer housing portion 24d reaches the layer 6 because the N₂ gas is flowing in the layer 5, the wafers W are exposed to the BTBAS gas in the layer 6 where the BTBAS gas is flowing from the gas supplying pipe 26c (FIG. 4). Therefore, the BTBAS gas molecules are adsorbed on the wafers W.

After a predetermined period of time required for the BTBAS gas molecules to be adsorbed on the wafers W has passed, the inner boat 24 is moved downward from the layer 6 by the second elevator 32 (FIG. 6D), and the wafer housing portion 24d returns to the layer 4 (FIG. 6E). Then, the inner boat 24 is further moved downward from the layer 4 to reach the layer 2 via the layer 3, as shown in FIG. 6G. When the wafer housing portion 24 is moving through the layer 5, 4, and 3, the wafers W are continuously exposed to the N₂ gas. While in this period of time an excessive amount of the BTBAS gas molecules adsorbed on the wafers W may be desorbed, a layer of BTBAS gas molecules may remain on the wafers W.

Because the O₃ gas is flowing from the gas supplying pipe 26a (FIG. 4) in the layer 2, the BTBAS gas molecules remaining on the wafers W are oxidized by the O₃ gas molecules, thereby forming a monolayer of silicon oxide.

Next, the inner boat 24 is moved upward by the second elevator 32 (FIG. 6H), the wafer housing portion 24d returns to the layer 4 from the layer 2 via the layer 3, as shown in FIG. 6A. Subsequently, the above cycle is repeated predetermined times, thereby depositing a silicon oxide film having a film thickness corresponding to the cycles. Incidentally, the cycle of the procedures shown in FIGS. 6A through 6H is performed, for example, 20 times per minute (20 cycles/min). In addition, while the inner boat 24 may be rotated while being moved vertically as described above, the rotation speed may be faster when the wafer housing portion 24d is in the layers 2 and 6, and slower when the wafer housing portion 24d is in the other layers, or the opposite.

Next, the BTBAS gas and the O₃ gas are stopped (Step S10 in FIG. 5), the inside of the outer tube 21 is purged with the N₂ gas (Step S11), and the temperature of the wafers W is decreased to a temperature TSDB at the time of standby (Step S12). In addition, after the N₂ gas is stopped (Step S13) and the outer tube 21 is evacuated to the lowest reachable pressure, the inside pressure of the outer tube 21 is increased to atmospheric pressure by supplying the N₂ gas (Step S14). Subsequently, the outer boat 23 and the inner boat 24 are unloaded from the outer tube 21 and the inner tube 22; the wafers W are unloaded by the wafer transfer unit (not shown); and thus the deposition process is completed.

As described above, the film deposition apparatus 10 according to an embodiment of the present invention includes the outer boat 23 providing the layer 6 where the BTBAS gas flows in the horizontal direction and the layer 2 where the O₃ gas flows in the horizontal direction, and the inner boat 24 having a wafer housing portion 24d configured to house and reciprocally move the wafers W between the layers 6 and 2 in the vertical direction. Therefore, the MLD can be realized only by the reciprocal vertical movement of the wafers W without a sequence of supplying the BTBAS gas, purging the BTBAS gas, supplying the O₃ gas, and purging the O₃ gas. Namely, the need for the purging steps is eliminated, and thus the deposition time is reduced at least by the time that used to be required for the purging steps, thereby improving the production throughput and reducing gas consumption.

In addition, because on/off operations of valves for starting/stopping supplying the BTBAS gas and the O₃ gas are not necessary, the working life of the valves can be increased, which leads to reductions in maintenance costs and thus the production costs.

Moreover, because the layers 3 through 5 where the N₂ gas flows in the horizontal direction are arranged between the layers 2 and 6, the BTBAS gas and the O₃ gas are prevented from being mixed with each other, thereby appropriately realizing the MLD mode film deposition. Furthermore, because the layer 7 where the N₂ gas flows in the horizontal direction is provided above the layer 6, and the layer 1 where the N₂ gas flows in the horizontal direction is provided below the layer 2, the BTBAS (O₃) gas is prevented from mixing with the O₃ (BTBAS) gas flowing in the layer 2 (6) through the space between the inner boat 24 and the inner tube 22. Therefore, the MLD mode film deposition is certainly realized.

In addition, because the gases may flow at substantially the same flow rate in the corresponding layers 1 through 7 while the volumes of the layers 1 through 7 are substantially equal to one another, the gases can provide a laminar flow in each layer. As a result, inter-layer mixing of the gases can be prevented. Namely, gas intermixing of the O₃ gas and the BTBAS gas rarely takes place, thereby certainly realizing the MLD mode film deposition.

Moreover, because the BTBAS gas molecules adsorbed on the wafers W are oxidized by the O₃ gas molecules adsorbed over the BTBAS molecules, silicon oxide is formed in only an area where the BTBAS gas molecules and the O₃ gas molecules can co-exist. Therefore, unwanted film deposition on, for example, the surfaces of the outer boat 23, the inner tube 22, the outer tube 21 and the like can be prevented, thereby reducing particle generation and thus improving the production throughput.

Moreover, because the BTBAS gas as the source gas and the O₃ gas as the oxidizing gas flow in limited areas of the layer 6 and 2, respectively, these gases may flow at higher concentrations, thereby enabling the gas molecules to be certainly adsorbed on the wafers W. In other words, gas usage efficiency can be improved by locally flowing the source gas and the oxidizing gas inside the outer tube 21.

Furthermore, because the inner boat 24 can be rotated, a reduction in the gas concentration along a gas flow direction due to consumption (adsorption) of the gas molecules on the wafers W (a depletion effect) can be compensated for, thereby allowing the gas molecules to be uniformly adsorbed on the wafers W and thus improving the film thickness uniformity.

In addition, because the film deposition apparatus 10 is configured as a so-called hot-wall type in which the wafers W are heated by the heater 12 arranged outside the outer tube 21, the temperature uniformity across the wafer can be improved, which allows the BTBAS gas molecules to be uniformly oxidized by the O₃ gas molecules, thereby improving the thickness and property uniformity across the wafer. Moreover, because the outer tube 21, the inner tube 22, the outer boat 23, and the inner boat 24 may be made of, for example, quartz, and SiC, if needed, they can be handled in a conventional manner.

While the present invention has been described with reference to the foregoing embodiments, the present invention is not limited to the disclosed embodiments, but may be modified or altered within the scope of the accompanying claims.

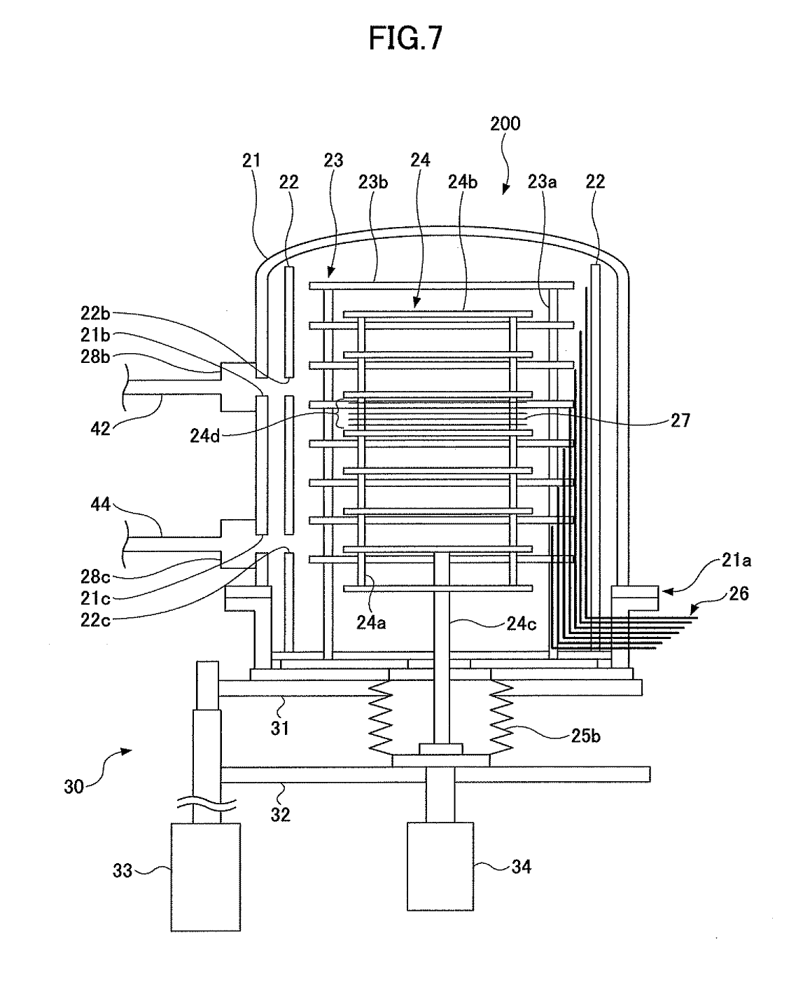

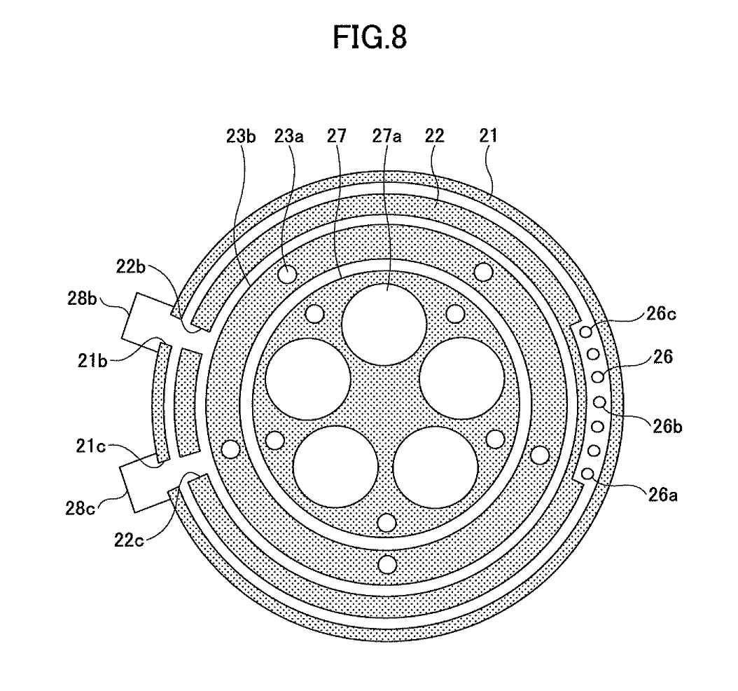

For example, the wafers W are housed in the wafer housing portion 24d of the inner boat 24 in the above embodiments, the wafer housing portion 24d may house a susceptor having wafer receiving portions for the wafers W in other embodiments. A film deposition apparatus 200 having such a configuration according to another embodiment of the present invention is shown in FIGS. 7 and 8. Referring to FIG. 7, the film deposition apparatus 200 is different from the film deposition apparatus 10 in that a susceptor 27 is housed in the wafer housing portion 24d of the inner boat 24 and the diameters of the outer tube 21, the inner tube 22, the outer boat 23, and the inner boat 24 are increased accordingly, and the film deposition apparatus 200 is substantially the same as the film deposition apparatus 10 in terms of other configurations. The susceptor 27 includes five wafer receiving portions 27a formed as, for example, concave portions. The number of the wafer receiving portions 27a is not limited to five, but may be arbitrarily adjusted. In addition, five susceptors 27 each having the five wafer receiving portions 27a may be housed in the wafer housing portion 24d, which enables a total of 25 wafers W to be processed in one run. With this, the film deposition apparatus 200 can have a smaller height, when compared with a case where the 25 wafers are housed one above another in a vertical direction.

In addition, while the MLD of silicon oxide using the BTBAS gas and the O₃ gas has been described in the above embodiments, oxygen plasma may be used instead of the O₃ gas in other embodiments. In order to supply the oxygen plasma, an oxygen plasma generator is provided instead of the ozone generator 51d (FIG. 1), and microwaves or high frequency waves having a frequency of 915 MHz, 2.45 GHz, 8.3 GHz or the like are supplied to predetermined electrodes arranged inside the oxygen plasma generator, thereby generating the oxygen plasma.

Moreover, the film deposition apparatus 10 may be used to deposit a silicon nitride film rather than the silicon oxide film. In this case, ammonia (NH₃), hydrazine (N₂H₂) and the like may be utilized as a nitriding gas for the silicon nitride film deposition.

In addition, as a source gas for the silicon oxide or nitride film deposition, dichlorosilane (DCS), hexadichlorosilane (HCD, tris(dimethylamino)silane (3DMAS), tetra ethyl ortho silicate (TEOS), and the like may be used rather than BTBAS.

Moreover, the film deposition apparatus according to an embodiment of the present invention may be used for an MLD of an aluminum oxide (Al₂O₃) film using trymethylaluminum (TMA) and O₃ or oxygen plasma, a zirconium oxide (ZrO₂) film using tetrakis(ethylmethylamino)zirconium (TEMAZ) and O₃ or oxygen plasma, a hafnium oxide (HfO₂) film using tetrakis(ethylmethylamino)hafnium (TEMAHf) and O₃ or oxygen plasma, a strontium oxide (SrO) film using bis(tetra methyl heptandionate) strontium (Sr(THD)₂) and O₃ or oxygen plasma, a titanium oxide (TiO) film using (methyl-pentadionate)(bis-tetra-methyl-heptandionate) titanium (Ti(MPD)(THD)) and O₃ or oxygen plasma, and the like, rather than the silicon oxide film and the silicon nitride film.

The wafer housing portion 24d of the inner boat 24 may house, for example, 5 through 50 wafers. A height of the inner boat 24, the outer boat 23, the inner tube 22, and the outer tube 21 may be determined in accordance with the number of wafers to be housed and a pitch between the wafers.

The annular plate 23b may be provided with a flow controlling plates that rise on the annular plate 23b near the gas supplying pipes 26. For example, the gas ejected from the gas supplying pipe 26 can be spread with a wider angle by the flow controlling plates, and thus the gas molecules can spread across the wafer in a shorter period of time, which may reduce a process time.

Moreover, for example, the two or three or more ejection holes 26H may be made in the gas supplying pipe 26 in accordance with the height of the layers 1 through 7 (distance between the two adjacent circular plates 24b), a distance between the gas supplying pipe 26 and the edge of the wafer W, and a kind of the gases. Furthermore, plural gas supplying pipes may be provided for one layer.

In addition, while the openings 21b, 22b and the evacuation port 28b are provided for the layer 6, and the openings 21c, 22c and the evacuation port 28c are provided for the layer 2 in the above embodiments (and their modifications), the same configurations may be made for the layer 4 or the other layers in other embodiments. Moreover, while the evacuation pipe 44 connected to the evacuation port 28c converges to the evacuation pipe 42 connected to the evacuation port 28b in the above embodiments (and their modifications), additional evacuation systems may be provided separately for the evacuation pipes 42 and 44. Moreover, another evacuation system for another layer may be provided.

In addition, while the film deposition apparatus according to the above embodiments (and their modifications) is configured so that the BTBAS gas and the O₃ gas flow in the layers 6 and 2 separated by the layers 3 through 5, respectively, the BTBAS gas may flow in an adjacent layer where the O₃ gas flows, and the wafer housing portion 24d of the inner boat 24 may be reciprocally moved between the two layers in other embodiments. Moreover, a film deposition apparatus according to other embodiments may be configured so that the O₃ gas flows in the layer 3, the N₂ gas flows in the layer 4, and the BTBAS gas flows in the layer 5. In other words, a layer where the BTBAS gas flows and another layer where the O₃ gas flows may be separated by one layer where the N₂ gas flows. Even in this case, the wafer housing portion 24d may be reciprocally moved between the layers 3 and 5, thereby realizing the MLD mode film deposition.

Furthermore, a film deposition apparatus according to an embodiment of the present invention may be configured as a horizontal type film deposition apparatus. In this case, the reaction chamber 20 extends in the horizontal direction; the circular plates 24b of the inner boat 24 and the annular plates 23b of the outer boat 23 are arranged at the same horizontal intervals; and the inner boat 24 is reciprocally moved relative to the outer boat 23 in the horizontal direction. In addition, the gas supplying pipes 26, the evacuation ports 28b, 28c, the evacuation pipes 42, 44 and the like are configured so that the gases flow in a vertical direction.

What is claimed is:

1. A film deposition apparatus comprising:
a plurality of first plate members arranged within a hermetically sealable cylindrical chamber, wherein the plurality of the first plate members are arranged in a first direction along a center axis of the chamber with a first clearance therebetween, each of the first plate members having an opening; and
a plurality of second plate members arranged in the first direction with the first clearance therebetween, wherein the plurality of the second plate members are reciprocally movable through the openings of the plurality of the first plate members,
wherein a first pair of first plate members among the plurality of the first plate members is configured to provide a first gas flow passage where a first gas flows in a second direction toward an inner circumferential surface of the chamber,
wherein a second pair of first plate members among the plurality of the first plate members is configured to provide a second gas flow passage where a second gas flows in the second direction, and wherein a pair of second plate members among the plurality of the second plate members is configured to provide a wafer housing portion configured to house a wafer.

2. The film deposition apparatus of claim 1, further comprising:
a first gas supplying portion configured to supply the first gas to the first gas flow passage; and
a second gas supplying portion configured to supply the second gas to the second gas flow passage.

3. The film deposition apparatus of claim 1, wherein a third pair of first plate members among the plurality of the first plate members is configured to provide a third gas flow passage where a third gas flows in the second direction.

4. The film deposition apparatus of claim 3, further comprising a third gas supplying portion configured to supply the third gas to the third gas flow passage.

5. The film deposition apparatus of claim 1, wherein the pair of the second plate members supports a plurality of the wafers.

6. The film deposition apparatus of claim 1, further comprising a heating portion arranged outside the chamber and configured to heat the wafer.

7. The film deposition apparatus of claim X, wherein the wafer housing portion houses a susceptor configured to support one or more wafers.

8. The film deposition apparatus of claim 1, further comprising a positioning member configured to position the plurality of the second plate members relative to the chamber, wherein the plurality of the first plate members are positioned via the positioning member.

9. A film deposition method performed in a film deposition apparatus including a plurality of first plate members arranged within a hermetically sealable cylindrical chamber, wherein the plurality of the first plate members are arranged in a first direction along a center axis of the chamber with a first clearance therebetween, each of the first plate members having an opening, and a plurality of second plate members arranged in the first direction with the first clearance therebetween, wherein the plurality of the second plate members are reciprocally movable through the openings of the plurality of the first plate members, the film deposition method comprising steps of:
loading a wafer into a space between a pair of second plate members among the plurality of the second plate members;
flowing a first gas to a space between a first pair of first plate members among the plurality of the first plate members in a second direction toward an inner circumferential surface of the chamber;
flowing a second gas to a space between a second pair of first plate members among the plurality of the first plate members in the second direction; and
reciprocally moving the plurality of the second plate members in order to alternately expose the wafer to the first gas and the second gas.

10. The film deposition method of claim 9, further comprising a step of flowing a third gas to a space between a third pair of first plate members among the plurality of the first plate members in the second direction, wherein the wafer is exposed to the first gas, the third gas, and the second gas in this order in the step of reciprocally moving the plurality of the second plate members.

11. A computer readable storage medium storing a program to perform a film deposition method of claim 9.
